(19) United States
(12) Patent Application Publication
(10) Pub. No.: US 2025/0241114 A1
(43) Pub. Date: Jul. 24, 2025

(54) ELECTROLUMINESCENCE DEVICE, PRODUCTION METHOD THEREOF, AND DISPLAY DEVICE INCLUDING THE SAME

(71) Applicants: SAMSUNG ELECTRONICS CO., LTD., Suwon-si (KR); The Governing Council of the University of Toronto, Ontario (CA)

(72) Inventors: Kwang Hee KIM, Suwon-si (KR); Ji Hyun MIN, Suwon-si (KR); Sjoerd Hoogland, Ontario (CA); Haoyue Wan, Ontario (CA); Euidae Jung, Ontario (CA); Edward Sargent, Ontario (CA); Shin Ae JUN, Suwon-si (KR)

(21) Appl. No.: 19/032,432

(22) Filed: Jan. 20, 2025

(30) Foreign Application Priority Data
Jan. 19, 2024 (KR) 10-2024-0009098

(51) Int. Cl. H10K 50/115; H10K 71/12

(52) U.S. Cl. CPC H10K 50/115; H10K 71/12

(57) ABSTRACT

An electroluminescence device includes an anode and a cathode opposite to each other, a light emitting layer between the anode and the cathode, an electron transport layer between the light emitting layer and the cathode, and a continuous metal or non-metal oxide film on the electron transport layer, where the light emitting layer includes a plurality of semiconductor nanoparticles, and the electron transport layer includes Group IIA metal-containing zinc oxide nanoparticles. In the electroluminescence device, the continuous metal or non-metal oxide film is produced by alternately depositing metal or non-metal precursors and water on the electron transport layer using an atomic layer deposition (ALD) method.

This application claims priority to and the benefit of Korean Patent Application No. 10-2024-0009098 filed in the Korean Intellectual Property Office on Jan. 19, 2024, the entire content of which in its entirety is herein incorporated by reference.

### BACKGROUND

### 1. Field

Embodiments of the disclosure relate to an electroluminescence device, a production method thereof, and a display device including the electroluminescence device.

### 2. Description of the Related Art

A semiconductor nanoparticle (e.g., a semiconductor nanocrystal particle) having a nanometer size may emit light. For example, a semiconductor nanoparticle including a semiconductor nanocrystal may exhibit a quantum confinement effect. For example, light emission from the semiconductor nanoparticle may occur when an electron in an excited state resulting from light excitation or an applied voltage transits from a conduction band to a valence band. The semiconductor particle may be configured to emit light of a desired wavelength region by adjusting a size and/or composition of the semiconductor nanoparticle. Nanoparticles may be used in a luminescence device (e.g., electroluminescence device) and a display device including the luminescence device.

### SUMMARY

Embodiments relate to a luminescence device that emits light by itself when voltage is applied to nanostructures (e.g., quantum dots).

Embodiments provide a display device (e.g., a quantum dot-light emitting diode (QD-LED) display) including a semiconductor nanoparticle (e.g., a quantum dot) as a light emitting material in one or more pixels.

In an embodiment, an electroluminescence device includes an anode and a cathode opposite to each other, a light emitting layer between the anode and cathode, an electron transport layer between the light emitting layer and the cathode, and a continuous metal or non-metal oxide film between the electron auxiliary layer and the cathode, where the light emitting layer includes a plurality of semiconductor nanoparticles, and the electron transport layer includes Group IIA metal-containing zinc oxide nanoparticles.

In an embodiment, the continuous metal or non-metal oxide film may include a material having a bandgap energy greater than a bandgap energy of the Group IIA metal-containing zinc oxide.

In an embodiment, the continuous metal or non-metal oxide film may include a material having a bandgap energy of greater than or equal to about 4.5 electron volts (eV).

In an embodiment, the continuous metal or non-metal oxide film may include an oxide of a metal including at least one selected from aluminum, silicon, tin, magnesium, tungsten, or a combination thereof.

In an embodiment, the continuous metal or non-metal oxide film may have a thickness of less than about 5 nanometers (nm).

In an embodiment, Group IIA metal (e.g., alkaline earth metal) may include at least one selected from magnesium, calcium, beryllium, strontium, barium, or combinations thereof.

In an embodiment, the Group IIA metal-containing zinc oxide nanoparticles may be represented by Zn₁₋ₓM¹ₓO, where M¹ comprises a Group IIA metal, and optionally further includes at least one selected from zirconium (Zr), tungsten (W), lithium (Li), titanium (Ti), yttrium (Y), aluminum (Al), gallium (Ga), indium (In), sodium (Na), potassium (K), cesium (Cs), tin (Sn), cobalt (Co), or vanadium (V), and x is greater than 0 and less than or equal to 0.3.

In an embodiment, the Group IIA metal-containing zinc oxide nanoparticles may be zinc magnesium oxide nanoparticles and a molar ratio of zinc to magnesium in the zinc magnesium oxide nanoparticles may be about 80:20 to about 95:5.

In an embodiment, the Group IIA metal-containing zinc oxide nanoparticles may have an average size of less than or equal to about 10 nm.

In an embodiment, the electron transport layer may have a thickness of greater than or equal to about 5 nm and less than about 60 nm.

In an embodiment, the plurality of semiconductor nanoparticles may have an average size of greater than or equal to about 7 nm and less than or equal to about 30 nm.

In an embodiment, each of the plurality of semiconductor nanoparticles may include a core including a first semiconductor nanocrystal, and a shell disposed on the core and including a second semiconductor nanocrystal different from the first semiconductor nanocrystal.

In an embodiment, the electroluminescence device may further include a hole auxiliary layer between the light emitting layer and the anode.

In an embodiment, the electroluminescence device has a maximum external quantum efficiency of greater than or equal to about 7%.

In an embodiment, the electroluminescence device has a maximum luminance of greater than or equal to about 1500 candelas per square meter (cd/m²).

In an embodiment, a method for producing an electroluminescence device includes forming a light emitting layer including semiconductor nanocrystals on a first electrode; forming an electron transport layer including Group IIA metal-containing zinc oxide nanoparticles on the light emitting layer; forming a continuous metal or non-metal oxide film on the electron transport layer; and forming a second electrode on the continuous metal or non-metal oxide film.

In an embodiment, the forming the continuous metal or non-metal oxide film may include alternately depositing metal or non-metal precursors and water on the electron transport layer using an atomic layer deposition (ALD) method.

In an embodiment, the forming the electron transport layer may include preparing a dispersion in which Group IIA metal-containing zinc oxide nanoparticles are dispersed in an organic solvent, and applying the dispersion onto the light emitting layer.

In an embodiment, the method for producing the electroluminescence device may further include forming a hole auxiliary layer before forming the light emitting layer on the first electrode.

In an embodiment, a display device includes the electroluminescence device.

In an embodiment, the display device may be or include a portable terminal device, a monitor, a notebook computer, a television, an electric sign board, a camera, or an electronic component.

According to embodiments, the electroluminescence device exhibits improved electroluminescence properties, such as lower driving voltage, reduced leakage current, higher current density, quantum efficiency, and luminance, and increased life-span, and does not require aging prior to operation after device production or can have a significantly reduced aging time. The electroluminescence device of the disclosure can exhibit a desired level of life-span characteristics along with luminous efficiency.

### BRIEF DESCRIPTION OF THE DRAWINGS

FIG. 1 is a schematic cross-sectional view of an electroluminescence device according to an embodiment.

FIG. 2 is a schematic cross-sectional view of an electroluminescence device according to an embodiment.

FIG. 3 is a schematic cross-sectional view of an electroluminescence device according to an embodiment.

FIG. 4 shows a schematic cross-sectional view of an electroluminescence device according to an embodiment.

FIG. 5 shows a schematic cross-sectional view of an electroluminescence device according to an embodiment.

FIG. 6 shows a schematic cross-sectional view of an electroluminescence device according to an embodiment.

FIG. 7 is a graph showing current density versus voltage of the electroluminescence devices according to Examples 1 to 3 and Comparative Example 1.

FIG. 8 is a graph showing EQE versus current density of the electroluminescence devices according to Examples 1 to 3 and Comparative Example 1.

FIG. 9 is a graph showing luminance versus voltage of the electroluminescence devices according to Examples 1 to 3 and Comparative Example 1.

FIG. 10 is a graph showing luminescence intensity versus time in the time-resolved photoluminescence concept of the electroluminescence devices according to Examples 1 to 3 and Comparative Example 1.

FIG. 11 is a graph showing current density versus voltage of the electroluminescence devices according to Comparative Example 1 and Example 2.

FIG. 12 is a graph showing luminance versus voltage of the electroluminescence devices according to Comparative Example 1 and Example 2.

FIG. 13 is a graph showing EQE versus luminance of the electroluminescence devices according to Comparative Example 1 and Example 2.

FIG. 14 is a graph showing luminescence intensity versus time of the electroluminescence devices according to Comparative Example 1 and Example 2.

FIG. 15 shows the emission spectra of the films including a light emitting layer that includes quantum dots (InP/ZnSe/ZnS) disposed under an electron transport layer that includes zinc magnesium oxide (ZnMgO) nanoparticles, on which an Al₂O₃ film is formed or not.

FIG. 16 is a graph showing luminescence intensity versus time of the films including a light emitting layer that includes quantum dots (InP/ZnSe/ZnS) disposed under an electron transport layer that includes zinc magnesium oxide (ZnMgO) nanoparticles, on which an Al₂O₃ film is formed or not.

FIG. 17 shows the emission spectra of the layers including zinc magnesium oxide (ZnMgO) nanoparticles formed on a glass substrate, on which an Al₂O₃ film is formed or not, where the luminescence occurs from a deep trap in the range of 500 nm to 550 nm within the bandgap of the zinc magnesium oxide nanoparticles.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In order to clearly explain the present disclosure, parts irrelevant to the description are omitted, and the same reference numerals are assigned to the same or similar elements throughout the specification.

The size and thickness of each constituent element as shown in the drawings are randomly indicated for better understanding and ease of description, and this disclosure is not necessarily limited to as shown. In the drawings, the thickness of layers, films, panels, regions, etc., are exaggerated for clarity. And in the drawings, for convenience of description, the thickness of some layers and regions are exaggerated.

In addition, it will be understood that when an element such as a layer, film, region, or substrate is referred to as being “on” another element, it can be directly on the other element or intervening elements may also be present therebetween. In contrast, when an element is referred to as being “directly on” another element, there are no intervening elements present. Also, to be disposed “on” the reference portion means to be disposed above or below the reference portion, and does not necessarily mean “above” in an opposite direction of gravity.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Further, in the entire specification, the term “planar phase” means a case in which a target part is viewed from the top, and the term “cross-sectional phase” means a case in which a cross-section of the target part that is cut in a vertical direction is viewed from the side.

In the drawings, the thickness of layers, films, panels, regions, etc., are exaggerated for clarity. Like reference numerals designate like elements throughout the specification.

Hereinafter, the value of the work function or (the highest occupied molecule orbital (HOMO) or the lowest un-occupied molecular orbital (LUMO)) energy level is expressed as an absolute value from the vacuum level. In addition, when the work function or the energy level is referred to be “deep,” “high” or “large,” the work function or the energy level has a large absolute value based on “0 eV” of the vacuum level, while when the work function or the energy level is referred to be “shallow,” “low,” or “small,” the work function or energy level has a small absolute value based on “0 eV” of the vacuum level.

As used herein, “metal” includes a semi-metal such as Si.

As used herein, when a definition is not otherwise provided, “substituted” refers to replacement of at least one hydrogen of a compound or the corresponding moiety by a substituent selected from a C1 to C30 alkyl group, a C1 to C30 alkenyl group, a C2 to C30 alkynyl group, a C6 to C30 aryl group, a C7 to C30 alkylaryl group, a C1 to C30 alkoxy group, a C1 to C30 heteroalkyl group, a C3 to C30 heteroalkylaryl group, a C3 to C30 cycloalkyl group, a C3 to C15 cycloalkenyl group, a C6 to C30 cycloalkynyl group, a C2 to C30 heterocycloalkyl group, a halogen (—F, —Cl, —Br, or —I), a hydroxy group (—OH), a nitro group (—NO₂), a cyano group (—CN), an amino group (—NRR′ where R and R′ are independently hydrogen or a C1 to C6 alkyl group), an azido group (—N₃), an amidino group (—C(═NH)NH₂), a hydrazino group (—NHNH₂), a hydrazono group (═N(NH₂)), an aldehyde group (—C(═O)H), a carbamoyl group (—C(O)NH₂), a thiol group (—SH), an ester group (—C(═O)OR, where R is a C1 to C6 alkyl group or a C6 to C12 aryl group), a carboxyl group (—COOH) or a salt thereof (—C(═O) OM, where M is an organic or inorganic cation), a sulfonic acid group (—SO₃H) or a salt thereof (—SO₃M, where M is an organic or inorganic cation), a phosphoric acid group (—PO₃H₂) or a salt thereof (—PO₃MH or —PO₃M₂, where M is an organic or inorganic cation), and a combination thereof.

Herein, the hydrocarbon group refers to a group containing carbon and hydrogen (e.g., an aliphatic group such as an alkyl, alkenyl, or alkynyl group, or an aromatic group such as an aryl group). The hydrocarbon group may be a group having a monovalence or more formed by removal of one or more hydrogen atoms from alkane, alkene, alkyne, or arene. In the hydrocarbon group of an embodiment, at least one methylene may be replaced by an oxide moiety, a carbonyl moiety, an ester moiety, −NH—, or a combination thereof. Unless otherwise stated to the contrary, the hydrocarbon (alkyl, alkenyl, alkynyl, or aryl) group may have 1 to 60, 2 to 32, 3 to 24, or 4 to 12 carbon atoms. The hydrocarbon group may or may not include a carboxylic acid group.

As used herein, “alkyl” refers to a linear or branched saturated monovalent hydrocarbon group (methyl, ethyl hexyl, etc.).

As used herein, “alkenyl” refers to a linear or branched monovalent hydrocarbon group having one or more carbon-carbon double bond.

As used herein, “alkynyl” refers to a linear or branched monovalent hydrocarbon group having one or more carbon-carbon triple bond.

As used herein, “aryl” refers to a group formed by removal of at least one hydrogen from an arene (e.g., a phenyl or naphthyl group).

As used herein, “hetero” refers to one including 1 to 3 heteroatoms of N, O, S, Si, P, or a combination thereof.

As used herein, “alkoxy” means an alkyl group linked via an oxygen (i.e., alkyl-O—), such as a methoxy, ethoxy, or sec-butyloxy group.

An “amine group” may be —NRR, where (Rs are each independently hydrogen, a C1 to C12 alkyl group, a C7 to C20 alkylaryl group, a C7 to C20 arylalkyl group, or a C6 to C18 aryl group.

Herein, the description that does not contain hazardous heavy metals such as cadmium may refer to a concentration of cadmium (or a corresponding heavy metal) of less than or equal to about 100 parts per million (ppm), less than or equal to about 50 ppm, less than or equal to about 10 ppm, or almost zero. In an embodiment, substantially no cadmium (or other heavy metal) is present, or, if present, in an amount or impurity level below the detection limit of a given detection means.

Unless otherwise stated, numerical ranges stated herein are inclusive.

Unless otherwise stated, the words “substantially” or “approximately” or “about” are omitted before values in the numerical ranges specified herein.

As used herein, “substantially” or “approximately” or “about” means not only the stated value, but also the mean within an acceptable range of deviations, considering the errors associated with the corresponding measurement and the measurement of the measured value. For example, “substantially”, “approximately”, or “about” can mean within +10%, 5%, 3%, or 1% or within standard deviation of the stated value.

Herein, a nanoparticle refers to at least a structure having at least one region or characteristic dimension with a nanoscale dimension. In an embodiment, the dimension of the nanoparticle may be less than or equal to about 300 nanometers (nm), less than or equal to about 250 nm, less than or equal to about 150 nm, less than or equal to about 100 nm, less than or equal to about 50 nm, or less than or equal to about 30 nm. Unless otherwise specified herein, the nanoparticles or semiconductor nanoparticles may have any shape, such as a nanowire, a nanorod, a nanotube, a multi-pod type shape having two or more pods, a nanodot (or a quantum dot), etc., but are not particularly limited. The nanoparticles may be, for example, substantially crystalline, substantially monocrystalline, polycrystalline, amorphous, or a combination thereof.

For example, semiconductor nanoparticles such as quantum dots can exhibit quantum confinement or exciton confinement. In this specification, the terms nanoparticle or quantum dot are not limited in shape unless specifically defined. Semiconductor nanoparticles, such as quantum dots, can have a size smaller than the diameter of the Bohr excitation in a bulk crystal of the same material and can exhibit quantum confinement effects. Quantum dots can emit light corresponding to their bandgap energy by controlling the size of the nanocrystal as the luminescent center.

Herein, T70 refers to time taken for luminance of a given device to decrease to 70% based on 100% of the initial luminance when the device is driven at predetermined luminance.

Herein, T90 refers to time taken for luminance of a given device to decrease to 90% based on 100% of the initial luminance when the device is driven at predetermined luminance.

Herein, external quantum efficiency (EQE) refers to a ratio of the number of photons emitted from a light emitting diode (LED) to the number of electrons passing through the device. EQE may be criteria of how efficiently the light emitting diode converts the electrons into the photons and allows them to escape. In an embodiment, EQE may be determined based on the following equation:

EQE=[Injection efficiency]×[Solid state quantum yield]×[Extraction efficiency]

In the equation above, the injection efficiency means the proportion of electrons passing through the device and injected into the active region, the solid state quantum yield means the proportion of all electron-hole recombinations in the active region that are radiative, and thus, produce photons, and the extraction efficiency means the proportion of photons generated in the active region, and then escaping the device.

Herein, the maximum external quantum efficiency refers to the maximum value of the external quantum efficiency.

Herein, the maximum luminance refers to a maximum value of luminance that the device can achieve.

Herein, the term ‘quantum efficiency’ can be interchangeably used with the ‘quantum yield’. Quantum efficiency (or quantum yield) may be measured either in solution or in a solid state (in a composite). In an embodiment, quantum efficiency (or quantum yield) is a ratio of the photons emitted to the photons absorbed by the nanostructure or population thereof. In an embodiment, quantum efficiency may be measured by any method. For example, for fluorescence quantum yield or efficiency, there may be two methods: an absolute method and a relative method.

In the absolute method, quantum efficiency is obtained by detecting the fluorescence of all samples through an integrating sphere. In the relative method, the quantum efficiency of an unknown sample is calculated by comparing the fluorescence intensity of the unknown sample with that of a standard dye (standard sample). Coumarin 153, Coumarin 545, Rhodamine 101 inner salt, Anthracene and Rhodamine 6G may be used as standard dyes according to their PL wavelengths, but the present disclosure is not limited thereto.

Energy bandgaps of semiconductor nanocrystal particles may be changed according to sizes, structures, and compositions of the nanocrystals. For example, as the sizes of the semiconductor nanocrystals increase, the semiconductor nanocrystals may have narrow energy bandgaps and increased emission wavelengths. Semiconductor nanocrystals are attracting attention as light emitting materials in various fields such as display devices, energy devices, and bioluminescence devices.

A semiconductor nanocrystal particle-based luminescence device (hereinafter, also referred to as QD-LED) that emits light when a voltage is applied includes a semiconductor nanocrystal particle as a light emitting material. QD-LED adopts a different emission principle from that of an organic light emitting diode (OLED) that emits light by using an organic material as an emission center and may realize purer colors (red, green, blue) and improved color reproducibility, and thus, is attracting attention as a next generation display device. QD-LED may be produced with a reduced cost by a solution process and may be expected to realize increased stability as it is based on an inorganic material, but technology development for improving device properties and life-span characteristics is desired.

In addition, quantum dots having electroluminescence properties at a practically applicable level may contain harmful heavy metals such as cadmium (Cd), lead, mercury, or a combination thereof. Accordingly, it is desirable to provide a light emitting device or a display device having a light emitting layer substantially free of the harmful heavy metal.

An electroluminescence device according to an embodiment is a self-luminous type light emitting device configured to emit a desired light by applying a voltage without a separate light source. Hereinafter, an electroluminescence device according to embodiments of the disclosure will be described with reference to the accompanying drawing.

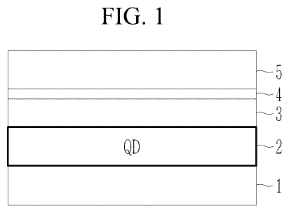

FIGS. 1 to 3 are schematic cross-sectional views of an electroluminescence device according to embodiments.

Referring to FIG. 1, an embodiment of the electroluminescence device includes an anode 1 and a cathode 5 that are spaced apart (e.g., disposed opposite to each other); a light emitting layer 2 disposed between the anode 1 and the cathode 5 and including a plurality of semiconductor nanoparticles; an electron transport layer 3 between the light emitting layer 2 and the cathode 5; and a continuous metal or non-metal oxide film 4 between the electron transport layer 3 and the cathode 5.

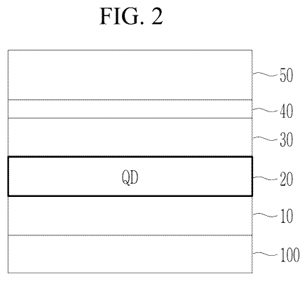

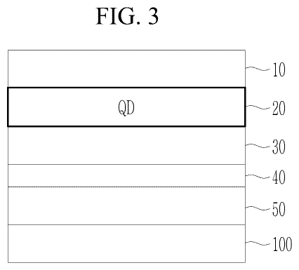

An electroluminescence device according to an embodiment may include an anode or a cathode disposed on a (transparent) substrate. A surface of the transparent substrate may define a light extraction surface. Referring to FIGS. 2 and 3, in an embodiment, an anode 10 or a cathode 50 is disposed on a (transparent) substrate 100, and a light emitting layer 20 is disposed between the anode 10 and the cathode 50. In such an embodiment, an electron transport layer 30 is arranged between the light emitting layer 20 and the cathode 50, and a continuous metal or non-metal oxide film 40 is disposed between the electron transport layer 30 and the cathode 50.

The cathode 5 or 50 may include an electron injection conductor. The anode 1 or 10 may include a hole injection conductor. The work function of the electron/hole injection conductor included in the cathode and the anode may be appropriately controlled and is not particularly limited. In an embodiment, for example, the cathode may have a small work function and the anode may have a relatively large work function, or vice versa.

The electron/hole injection conductor may include a metal-based material, e.g., a metal, a metal compound, an alloy, or a combination thereof, including, such as, for example, aluminum, magnesium, tungsten, nickel, cobalt, platinum, palladium, calcium, LiF, etc., a metal oxide, such as, for example, gallium indium oxide or indium tin oxide (ITO), or a conductive polymer (e.g., having a relatively high work function), such as, for example, polyethylene dioxythiophene, but are not limited thereto.

At least one of the anode and the cathode may be a light transmitting electrode or a transparent electrode. In an embodiment, both the anode and the cathode may be a light transmitting electrode. The electrode(s) may be patterned. The anode and/or the cathode may be disposed on a (e.g., insulating) substrate 100. The substrate 100 may be optically transparent (e.g., may have a light transmittance of greater than or equal to about 50%, greater than or equal to about 60%, greater than or equal to about 70%, greater than or equal to about 80%, greater than or equal to about 85%, or greater than or equal to about 90%, and for example, less than or equal to about 99%, or less than or equal to about 95%). The substrate may include a region for a blue pixel, a region for a red pixel, a region for a green pixel, or a combination thereof. A thin film transistor may be disposed in each of the regions of the substrate mentioned above, and one of a source electrode and a drain electrode of the thin film transistor may be electrically connected to the anode or the cathode.

The light transmitting electrode may be disposed on a (e.g., insulating) transparent substrate. The substrate may be rigid or flexible. The substrate may include or be made of plastic, glass, or a metal.

The light transmitting electrode may include or be made of, for example, a transparent conductor such as ITO or indium zinc oxide (IZO), gallium indium tin oxide, zinc indium tin oxide, titanium nitride, polyaniline, LiF/Mg:Ag, or the like, or a thin metal thin film of a single layer or a plurality of layers, but is not limited thereto. In an embodiment where one of the anode and the cathode is an opaque electrode, the one of the anode and the cathode may include or be made of an opaque conductor such as aluminum (Al), a lithium-aluminum (Li:Al) alloy, a magnesium-silver alloy (Mg; Ag), and lithium fluoride-aluminum (LiF:Al).

The thickness of the electrode (anode and/or cathode) is not particularly limited and may be appropriately selected in consideration of device efficiency. For example, the thickness of the electrode may be greater than or equal to about 5 nm, for example, greater than or equal to about 10 nm, greater than or equal to about 20 nm, greater than or equal to about 30 nm, greater than or equal to about 40 nm, or greater than or equal to about 50 nm. For example, the thickness of the electrode may be less than or equal to about 100 μm, for example, less than or equal to about 90 μm, less than or equal to about 80 μm, less than or equal to about 70 μm, less than or equal to about 60 μm, less than or equal to about 50 μm, less than or equal to about 40 μm, less than or equal to about 30 μm, less than or equal to about 20 μm, less than or equal to about 10 μm, less than or equal to about 1 μm, less than or equal to about 900 nm, less than or equal to about 500 nm, or less than or equal to about 100 nm.

The light emitting layer 2 or 20 includes semiconductor nanoparticle(s) (e.g., blue light emitting nanoparticles, red light emitting nanoparticles, or green light emitting nanoparticles). The light emitting layer may include one or more (e.g., 2 or more or 3 or more and 10 or less) monolayers of a plurality of nanoparticles.

The light emitting layer may be patterned or have a patterned shape. In an embodiment, the patterned light emitting layer may include a blue light emitting layer (e.g., a portion of the patterned light emitting layer disposed within a blue pixel in a display device to be described later), a red light emitting layer (e.g., a portion of the patterned light emitting layer disposed within a red pixel in a display device to be described later), and a green light emitting layer (e.g., a portion of the patterned light emitting layer disposed within a green pixel in a display device to be described later)), or a combination thereof. Each of the light emitting layers may be (e.g., optically) separated from an adjacent light emitting layer by a partition wall. In an embodiment, a partition wall such as a black matrix may be disposed between the red light emitting layer(s), the green light emitting layer(s), and the blue light emitting layer(s). In embodiments, the red light emitting layer, the green light emitting layer, and the blue light emitting layer may each be substantially optically isolated, e.g., when viewed in a plan view.

In an embodiment of the disclosure, the semiconductor nanoparticles in the light emitting layer may exhibit a zinc blende crystal structure. In an embodiment of the disclosure, the semiconductor nanoparticles may not exhibit a perovskite crystal structure.

The light emitting layer or semiconductor nanoparticle(s) may not include cadmium. The light emitting layer or semiconductor nanoparticle(s) may not contain mercury, lead, or a combination thereof.

In an embodiment, the semiconductor nanoparticles may have a core-shell structure. The semiconductor nanoparticles may include a core including a first semiconductor nanocrystal, and a shell disposed on the core and including a second semiconductor nanocrystal having a composition different from that of the first semiconductor nanocrystal.

The semiconductor nanoparticles (e.g., first semiconductor nanocrystal and/or the second semiconductor nanocrystal) may include a Group II-VI compound, a Group III-V compound, a Group IV-VI compound, a Group IV element or compound, a Group I-III-VI compound, a Group I-II-IV-VI compound, or a combination thereof. The light emitting layer (or semiconductor nanoparticles, first semiconductor nanocrystal, or second semiconductor nanocrystal) may not include hazardous heavy metals such as cadmium, lead, mercury, or a combination thereof.

The Group II-VI compound may be a binary compound selected from ZnS, ZnSe, ZnTe, ZnO, HgS, HgSe, HgTe, MgSe, MgS, and a mixture thereof; a ternary compound selected from ZnSeS, ZnSeTe, ZnSTe, HgSeS, HgSeTe, HgSTe, HgZnS, HgZnSe, HgZnTe, MgZnSe, MgZnS, and a mixture thereof; and a quaternary compound selected from HgZnTeS, HgZnSeS, HgZnSeTe, HgZnSTe, and a mixture thereof. The Group II-VI compound may further include a Group III metal.

The Group III-V compound may be a binary compound selected from GaN, GaP, GaAs, GaSb, AlN, AlP, AlAs, AlSb, InN, InP, InAs, InSb, and a mixture thereof; a ternary compound selected from GaNP, GaNAs, GaNSb, GaPAs, GaPSb, AlNP, AlNAs, AlNSb, AlPAS, AlPSb, InNP, InNAs, InNSb, InPAs, InPSb, and a mixture thereof; and a quaternary compound selected from GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. The Group III-V compound may further include a Group II element. An example of such a semiconductor nanocrystal is InZnP.

The Group IV-VI compound may be a binary compound selected from SnS, SnSe, SnTe, and a mixture thereof; a ternary compound selected from SnSeS, SnSeTe, SnSTe, and a mixture thereof; and a quaternary compound such as SnSSeTe.

Examples of the Group I-III-VI compound include CuInSe₂, CuInS₂, CuInGaSe, CuInGaS but are not limited thereto.

Examples of the group I-II-IV-VI compound include, but are not limited to, CuZnSnSe and CuZnSnS.

The Group IV element or compound is a single element selected from Si, Ge, and a mixture thereof; and a binary compound selected from SiC, SiGe, and a mixture thereof.

In an embodiment, the first semiconductor nanocrystal may include a metal including indium, zinc, or a combination thereof, and a non-metal including phosphorus, selenium, tellurium, sulfur, or a combination thereof. In an embodiment, the second semiconductor nanocrystal may include a metal including indium, zinc, or a combination thereof, and a non-metal including phosphorus, selenium, tellurium, sulfur, or a combination thereof.

In an embodiment, the first semiconductor nanocrystal may include InP, InZnP, ZnSe, ZnSeS, ZnSeTe, or a combination thereof and/or the second semiconductor nanocrystal may include ZnSe, ZnSeS, ZnS, ZnTeSe, or a combination thereof. In an embodiment, the shell may include zinc, sulfur, and optionally selenium in the outermost layer thereof.

In an embodiment, the semiconductor nanoparticles may emit blue or green light and have a core including ZnSeTe, ZnSe, or a combination thereof and a shell including zinc chalcogenide (e.g., ZnS, ZnSe, and/or ZnSeS). A content of sulfur in the shell may increase or decrease in the radial direction (from the core towards the surface).

In an embodiment, the semiconductor nanoparticles may emit red or green light, the core may include InP, InZnP, or a combination thereof, and the shell may include a Group 2 metal including zinc and a non-metal including at least one selected from sulfur and selenium.

In an embodiment, when the semiconductor nanoparticles have a core/shell structure, an alloyed layer may or may not be present at the interface between the core and the shell. The alloyed layer may be a homogeneous alloy or may be a gradient alloy. In the gradient alloy, a concentration of elements present in the shell may have a concentration gradient that changes in the radial direction (e.g., decreases or increases toward the center).

In an embodiment, the shell may have a composition which is changed in a radial direction. In an embodiment, the shell may be a multilayered shell including two or more layers. In the multilayered shell, adjacent two layers may have different compositions from each other. In the multilayered shell, at least one layer may each independently include a semiconductor nanocrystal having a single composition. In the multilayered shell, at least one layer may independently have an alloyed semiconductor nanocrystal. In the multilayered shell, at least one layer may have a concentration gradient that radially changes in terms of a composition of a semiconductor nanocrystal.

In the core/shell structured semiconductor nanoparticle, the bandgap energy of the shell material may be greater than that of the core material, but is not limited thereto. The bandgap energy of the shell material may be smaller than that of the core material. In the case of the multilayered shell, the energy bandgap of the outermost layer material of the shell may be greater than those of the core and the inner layer material of the shell (layers that are closer to the core). In the multilayered shell, a semiconductor nanocrystal of each layer is selected to have an appropriate bandgap, thereby effectively showing a quantum confinement effect.

In an embodiment, the semiconductor nanoparticles may include, for example, an organic ligand, an organic solvent, or a combination thereof, in a state in which they are bonded or coordinated to the surface.

In an embodiment, the semiconductor nanoparticle(s) may control the absorption/emission wavelength by, for example, adjusting its composition and/or size. The semiconductor nanoparticles included in the light emitting layer 2 or 20 may be configured to emit light of a desired or specific color. The semiconductor nanoparticles may include blue light emitting semiconductor nanoparticles, green light emitting semiconductor nanoparticles, or red light emitting semiconductor nanoparticles.

The maximum emission wavelength of the semiconductor nanoparticles can be in a wavelength range from ultraviolet to infrared wavelengths or higher. For example, the maximum emission wavelength of the semiconductor nanoparticle may be greater than or equal to about 300 nm, for example, greater than or equal to about 500 nm, greater than or equal to about 510 nm, greater than or equal to about 520 nm, greater than or equal to about 530 nm, greater than or equal to about 540 nm, greater than or equal to about 550 nm, greater than or equal to about 560 nm, greater than or equal to about 570 nm, greater than or equal to about 580 nm, greater than or equal to about 590 nm, greater than or equal to about 600 nm, or greater than or equal to about 610 nm. The maximum emission wavelength of the semiconductor nanoparticle may be less than or equal to about 800 nm, for example, less than or equal to about 650 nm, less than or equal to about 640 nm, less than or equal to about 630 nm, less than or equal to about 620 nm, less than or equal to about 610 nm, less than or equal to about 600 nm, less than or equal to about 590 nm, less than or equal to about 580 nm, less than or equal to about 570 nm, less than or equal to about 560 nm, less than or equal to about 550 nm, or less than or equal to about 540 nm. In an embodiment, for example, the maximum emission wavelength of the semiconductor nanoparticle may be in a range of about 500 nm to about 650 nm.

The semiconductor nanoparticles or the light emitting layer may emit green light, and the maximum emission wavelength may be in the range of greater than or equal to about 500 nm (e.g., greater than or equal to about 510 nm) and less than or equal to about 560 nm (e.g., less than or equal to about 540 nm). The semiconductor nanoparticles or the light emitting layer may emit red light, and the maximum emission wavelength may be in the range of greater than or equal to about 600 nm (e.g., greater than or equal to about 610 nm) and less than or equal to about 650 nm (e.g., less than or equal to about 640 nm). The semiconductor nanoparticles or the light emitting layer may emit blue light and the maximum emission wavelength may be greater than or equal to about 440 nm (e.g., greater than or equal to about 450 nm) and less than or equal to about 480 nm (e.g., less than or equal to about 465 nm).

The semiconductor nanoparticles or light emitting layer may exhibit a photoluminescence spectrum with a relatively narrow full width at half maximum (FWHM). In an embodiment, the semiconductor nanoparticle or light emitting layer may have FWHM less than or equal to about 45 nm, for example less than or equal to about 44 nm, less than or equal to about 43 nm, less than or equal to about 42 nm, less than or equal to about 41 nm, less than or equal to about 40 nm, less than or equal to about 39 nm, less than or equal to about 38 nm, less than or equal to about 37 nm, less than or equal to about 36 nm, or less than or equal to about 35 nm in the photoluminescence spectrum thereof.

The semiconductor nanoparticle or light emitting layer may have (e.g., be configured to implement) a quantum yield of greater than or equal to about 10%, for example, greater than or equal to about 20%, greater than or equal to about 30%, greater than or equal to about 40%, greater than or equal to about 50%, greater than or equal to about 60%, greater than or equal to about 70%, greater than or equal to about 80%, greater than or equal to about 90%, or even about 100%.

The semiconductor nanoparticle may have a size (e.g., a particle diameter or an equivalent diameter calculated from a two-dimensional area confirmed by electron microscopy analysis in the case of non-spherical particles) of greater than or equal to about 1 nm and less than or equal to about 100 nm. In an embodiment, the semiconductor nanoparticle may have a size of about 1 nm to about 50 nm, for example, about 2 nm (or about 3 nm) to about 35 nm. In an embodiment, the size of the semiconductor nanoparticle may be greater than or equal to about 1 nm, greater than or equal to about 2 nm, greater than or equal to about 3 nm, greater than or equal to about 4 nm, or greater than or equal to about 5 nm. In an embodiment, the size of the semiconductor nanoparticle may be less than or equal to about 50 nm, less than or equal to about 40 nm, less than or equal to about 30 nm, less than or equal to about 25 nm, less than or equal to about 20 nm, less than or equal to about 19 nm, less than or equal to about 18 nm, less than or equal to about 17 nm, less than or equal to about 16 nm, or less than or equal to about 15 nm.

The semiconductor nanoparticle may have any shape. In an embodiment, the shape of the semiconductor nanoparticle may be a sphere, a polyhedron, a pyramid, a multi-pod, a cube, a nanotube, a nanowire, a nanofiber, a nanosheet, a nanoplate, or a combination thereof.

The semiconductor nanoparticle may be synthesized by any method. For example, the semiconductor nanocrystal having a size of several nanometers may be synthesized through a wet chemical process. In the wet chemical process, crystal particles are grown by reacting precursor materials in an organic solvent, and growth of crystals may be controlled by coordinating the organic solvent or ligand compound on the surface of the semiconductor nanocrystals.

In an embodiment, for example, the method of preparing the semiconductor nanoparticles having the core/shell structure may include obtaining the core; preparing a first shell precursor solution including a first shell precursor including (e.g., zind,) and an organic ligand; preparing a second shell precursor including a non-metal element (e.g., sulfur, selenium, or a combination thereof); and heating the first shell precursor solution at a reaction temperature (e.g., greater than or equal to about 180° C., greater than or equal to about 200° C., greater than or equal to about 240° C., or greater than or equal to about 280° C. and less than or equal to about 360° C., less than or equal to about 340° C., or less than or equal to about 320° C.) and then, adding the core and the second shell precursor thereto to form a shell of second semiconductor nanocrystals on the first semiconductor nanocrystal core. In the semiconductor nanoparticles of an embodiment, the core may be prepared by an appropriate method. The method may further include preparing a core solution by separating the core from a reaction system used for preparing the core and then, dispersing it in an organic solvent.

In an embodiment, in order to form the shell, a solvent and optionally, a ligand compound are heated at a predetermined temperature (e.g., greater than or equal to about 100° C.) under vacuum (or vacuum-treated) and then, after converting the atmosphere into an inert gas atmosphere, heat-treated again at a predetermined temperature (e.g., greater than or equal to 100° C.). Subsequently, the core is added thereto, and the shell precursors are sequentially or simultaneously added thereto and then, heated at a predetermined reaction temperature to perform a reaction. The shell precursors may be sequentially introduced in different proportions during the reaction time.

The organic solvent may include a C6 to C22 primary amine such as a hexadecylamine, a C6 to C22 secondary amine such as dioctylamine, a C6 to C40 tertiary amine such as a trioctyl amine, a nitrogen-containing heterocyclic compound such as pyridine, a C6 to C40 olefin such as octadecene, a C6 to C40 aliphatic hydrocarbon such as hexadecane, octadecane, or squalane, an aromatic hydrocarbon substituted with a C6 to C30 alkyl group such as phenyldodecane, phenyltetradecane, or phenyl hexadecane, a primary, secondary, or tertiary phosphine (e.g., trioctylphophine) substituted with at least one (e.g., 1, 2, or 3) C6 to C22 alkyl group, a phosphine oxide (e.g. trioctylphosphine oxide) substituted with a (e.g., 1, 2, or 3) C6 to C22 alkyl group, a C12 to C22 aromatic ether such as phenyl ether or benzyl ether, or a combination thereof.

The organic ligand coordinates the surface of the manufactured semiconductor nanoparticles and can enable the semiconductor nanoparticles to be well dispersed in a solution. The organic ligand may include RCOOH, RNH₂, R₂NH, R₃N, RSH, RH₂PO, R₂HPO, R₃PO, RH₂P, R₂HP, R₃P, ROH, RCOOR′, RPO(OH)₂, R₂POOH, where, R and R′ each independently include substituted or unsubstituted C1 or more, C6 or more, or C10 or more and C40 or less, C35 or less, or C25 or less aliphatic hydrocarbon group, or substituted or unsubstituted C6 to C40 aromatic hydrocarbon group, or a combination thereof), or a combination thereof. The ligands may be used alone or as a mixture of two or more compounds.

The semiconductor nanocrystals may be recovered by pouring into an excess of nonsolvent to remove excess organic matter not coordinated on the surface, and centrifuging the resulting mixture. The nonsolvent may be a polar solvent that is miscible with the solvent used in the core formation and/or shell formation reactions and is not capable of dispersing the prepared nanocrystals. The nonsolvent may be selected depending on the solvent used in the reaction and may include, for example, acetone, ethanol, butanol, isopropanol, ethanediol, water, tetrahydrofuran (THF), dimethylsulfoxide (DMSO), diethylether, formaldehyde, acetaldehyde, a solvent having a similar solubility parameter to the foregoing solvents, or a combination thereof. The semiconductor nanocrystal particles may be separated through centrifugation, sedimentation, chromatography, or distillation. The separated nanocrystals may be added to a washing solvent and washed, if needed. The washing solvent has no particular limit and may have a similar solubility parameter to that of the ligand and may, for example, include hexane, heptane, octane, chloroform, toluene, benzene, and the like.

The semiconductor nanoparticles may be non-dispersible or water-insoluble in water, the aforementioned nonsolvent, or a combination thereof. The semiconductor nanoparticles may be dispersed in the aforementioned organic solvent. In an embodiment, the semiconductor nanoparticles may be dispersed in a substituted or unsubstituted C6 to C40 aliphatic hydrocarbon, a substituted or unsubstituted C6 to C40 aromatic hydrocarbon, or a combination thereof.

The surface of the prepared semiconductor nanoparticles may be treated with a halogen compound. By halogen treatment, some organic ligands present in the semiconductor nanoparticles may be replaced with a halogen. The halogen-treated semiconductor nanoparticles may include a reduced content of organic ligand. The halogen treatment may be performed by contacting semiconductor nanoparticles with a halogen compound (e.g., a metal halide such as zinc chloride) at a predetermined temperature, for example, about 30° C. to about 100° C., or about 50° C. to about 150° C. in an organic solvent. The halogen-treated semiconductor nanoparticles may be separated using the aforementioned nonsolvent.

In a display device or luminescence device, the thickness of the light emitting layer may be appropriately selected or determined. In an embodiment, the light emitting layer may include a monolayer(s) of semiconductor nanoparticles. In another embodiment, the light emitting layer may include one or more, for example, two or more, three or more, or four or more and 20 or less, 10 or less, 9 or less, 8 or less, 7 or less, or 6 or less monolayers of the semiconductor nanoparticles. The light emitting layer may have a thickness of greater than or equal to about 5 nm, for example, greater than or equal to about 10 nm, greater than or equal to about 15 nm, greater than or equal to about 20 nm, greater than or equal to about 25 nm, or greater than or equal to about 30 nm and less than or equal to about 200 nm, for example, less than or equal to about 150 nm, less than or equal to about 100 nm, less than or equal to about 90 nm, less than or equal to about 80 nm, less than or equal to about 70 nm, less than or equal to about 60 nm, or less than or equal to about 50 nm, and the light emitting layer may have a thickness of, for example about 10 nm to about 150 nm, for example about 20 nm to about 100 nm, for example about 30 nm to about 50 nm.

The light emitting layer may have a single layer or a multilayer structure in which two or more layers are stacked. Adjacent layers in the multilayer structure (e.g., a first light emitting layer and a second light emitting layer) may be configured to emit light of a same color. In a multilayer structure, adjacent layers (e.g., a first light emitting layer and a second light emitting layer) may have the same or different compositions and/or ligands from each other. In an embodiment, the light emitting layer or the multilayer light emitting layer including two or more layers may have a halogen content that changes in a thickness direction. In the (multilayer) light emitting layer according to an embodiment, the halogen content may increase towards the electron auxiliary layer. In the (multilayer) light emitting layer according to an embodiment, the organic ligand content may decrease towards the electron auxiliary layer. In the light emitting layer according to an embodiment, the halogen content may decrease toward the electron auxiliary layer. In the (multilayer) light emitting layer according to an embodiment, the organic ligand content may increase towards the electron auxiliary layer.

In an embodiment, the forming of the light emitting layer 2 or 20 including semiconductor nanoparticles may be performed by obtaining coating liquid including semiconductor nanoparticles and an organic solvent (e.g., an alkane solvent such as octane or heptane, an aromatic solvent such as toluene, or a combination thereof), and applying or depositing the coating liquid on an anode or a charge auxiliary layer (e.g., a hole auxiliary layer) by an appropriate method (e.g., spin coating, inkjet printing, etc.). The type of the organic solvent for the coating liquid is not particularly limited and may be appropriately selected. In an embodiment, the organic solvent may include an (substituted or unsubstituted) aliphatic hydrocarbon organic solvent, an (substituted or unsubstituted) aromatic hydrocarbon organic solvent, an acetate solvent, or a combination thereof.

In an electroluminescence device according to an embodiment, an electron transport layer 3 or 30 based on zinc oxide nanoparticles including a Group IIA metal is provided on the light emitting layer 2 or 20. Although not intended to be bound by a particular theory, it is understood that the presence of Group IIA metals may contribute to suppressing exciton quenching and improving electron transport in the light emitting layer based on semiconductor nanocrystals by reducing oxygen vacancies or defects within the ETL. However, according to what the inventors of the invention have confirmed, the combination of an electron auxiliary layer based on Group IIA metal-containing zinc oxide nanoparticles and an emitting layer based on semiconductor nanoparticles may be difficult to provide both a desired level of electroluminescence properties and desired life-span characteristics. Although not intended to be bound by a particular theory, it is thought that the metal oxide nanoparticles in the electron transport layer may have deep trap bands, and that the trap levels in the electron transport layer may result in the increase in leakage current and negatively affect the electroluminescence properties of the device. On the other hand, a QD-LED device including Group IIA metal-containing zinc oxide nanoparticles in an electron transport layer exhibits performance improvement over time after fabrication of the device and before its operation, for which various causes are assumed, such as, for example, an increase in conductivity according to surface changes of the Group IIA metal-containing zinc oxide nanoparticles over time, surface reactions among the nanoparticles, or penetration of aluminum into the electron transport layer during electrode deposition of the aluminum and the like or formation of aluminum oxide at the interface between the electron transport layer and the aluminum electrode, etc., an increase in characteristics due to penetration of a component from an ultraviolet curable resin that forms a sealing layer of the device, or the like. The inventors of the application have also confirmed that the characteristics of the QD-LED device including the Group IIA metal-containing zinc oxide nanoparticles in the electron transport layer are improved by allowing the device to stand at about 70° C. in an oven for a long time before its operation. Accordingly, it may be desired a method of shortening the process time as well as improving the characteristics of the QD-LED device by accelerating the aging treatment capable of improving the characteristics of the QD-LED device.

The electroluminescence device according to an embodiment includes Group IIA (i.e., Group 2A) metal-containing zinc oxide nanoparticles in an electron transport layer disposed on (e.g., directly on) a light emitting layer. Accordingly, such an electroluminescence device may have problems such as presence of a trap band in the electron transport layer in which the Group IIA metal-containing zinc oxide nanoparticles are included, and thereby, an increase in a leakage current, a trap emission of the electron transport layer itself, a decrease in luminous intensity of the light emitting layer including semiconductor nanoparticles, and the like. Accordingly, as a method for resolving the problems, a post process of the device fabrication, such as, for example, aging, may be desired. In this regard, an embodiment of the disclosure provides an electroluminescence device capable of improving electroluminescence properties, a life-span, and the like, even if the aging treatment time is dramatically shortened, or even no aging treatment is performed, by effectively passivating a trap in the electron transport layer including the Group IIA metal-containing zinc oxide nanoparticles, and thereby, exerting various desired effects of suppressing exciton quenching in the semiconductor nanocrystal-based light emitting layer by the electron transport layer including the Group IIA metal-containing zinc oxide nanoparticles and/or improving electron transport properties. The desired effects of the electroluminescence device according to an embodiment may be achieved by a continuous metal or non-metal oxide film formed on the electron transport layer.

In an embodiment, the Group IIA metal may include magnesium, calcium, beryllium, barium, strontium, or a combination thereof. In an embodiment, the zinc oxide nanoparticles include zinc magnesium oxide. In an embodiment, the zinc oxide nanoparticles may further include Zr, W, Li, Ti, Y, Al, gallium, indium, sodium (Na), potassium (K), cesium (Cs), tin (Sn), cobalt (Co), vanadium (V), or a combination thereof. In an embodiment, the Group IIA metal-containing zinc oxide nanoparticles may further include a halogen, such as fluorine, to modulate electron transport properties.

In an embodiment, the Group IIA metal-containing zinc oxide may include Zn₁₋ₓM¹ₓO, where M¹ includes a Group IIA metal, and optionally further includes at least one selected from zirconium (Zr), tungsten (W), lithium (Li), titanium (Ti), yttrium (Y), aluminum (Al), gallium (Ga), indium (In), sodium (Na), potassium (K), cesium (Cs), tin (Sn), cobalt (Co), or vanadium (V), and 0<x≤0.3. Herein, in the above chemical formula, x may be greater than or equal to about 0.01, greater than or equal to about 0.03, greater than or equal to about 0.05, greater than or equal to about 0.07, greater than or equal to about 0.1, greater than or equal to about 0.13, greater than or equal to about 0.15, greater than or equal to about 0.17, greater than or equal to about 0.18, greater than or equal to about 0.19, greater than or equal to about 0.2, greater than or equal to about 0.21, greater than or equal to about 0.22, greater than or equal to about 0.23, greater than or equal to about 0.25, greater than or equal to about 0.27, or greater than or equal to about 0.29. The x may be less than or equal to about 0.3, less than or equal to about 0.27, less than or equal to about 0.25, less than or equal to about 0.23, less than or equal to about 0.20, less than or equal to about 0.18, less than or equal to about 0.16, less than or equal to about 0.15, less than or equal to about 0.14, less than or equal to about 0.13, less than or equal to about 0.12, less than or equal to about 0.11, less than or equal to about 0.10, less than or equal to about 0.09, less than or equal to about 0.08, less than or equal to about 0.07, less than or equal to about 0.06, or less than or equal to about 0.05.

In an embodiment, the Group IIA metal-containing zinc oxide may include magnesium, or M¹ may be magnesium. The Group IIA metal-containing zinc oxide may include Zn₁₋ₓMgₓO (x may be greater than 0 and less than or equal to about 0.2, and for example, x may be about 0.05 to about 0.2, for example, about 0.05 to about 0.15, for example, about 0.1 to about 0.2, for example, about 0.1 to about 0.15, or, for example, about 0.15 to about 0.2). That is, the Group IIA metal-containing zinc oxide nanoparticles may be zinc magnesium oxide nanoparticles. In such an embodiment, a molar ratio of zinc to magnesium in the zinc magnesium oxide nanoparticles is about 80:20 to about 95:5.

The Group IIA metal-containing zinc oxide nanoparticles may have an average size of greater than or equal to about 1 nm, greater than or equal to about 2 nm, greater than or equal to about 2.5 nm, greater than or equal to about 3 nm, greater than or equal to about 3.5 nm, greater than or equal to about 4 nm, greater than or equal to about 4.5 nm, greater than or equal to about 5 nm, greater than or equal to about 5.5 nm, greater than or equal to about 6 nm, greater than or equal to about 6.5 nm, greater than or equal to about 7 nm, greater than or equal to about 7.5 nm, greater than or equal to about 8 nm, greater than or equal to about 8.5 nm, greater than or equal to about 9 nm, or greater than or equal to about 9.5 nm, and less than or equal to about 10 nm, less than or equal to about 9 nm, less than or equal to about 8 nm, less than or equal to about 7 nm, less than or equal to about 6 nm, less than or equal to about 5 nm, less than or equal to about 4.5 nm, less than or equal to about 4 nm, less than or equal to about 3.5 nm, less than or equal to about 3 nm, less than or equal to about 2.5 nm, less than or equal to about 2 nm, less than or equal to about 1.5 nm, or less than or equal to about 1 nm. For example, the Group IIA metal-containing zinc oxide nanoparticles may have an average size of about 2 nm to about 10 nm, for example, about 3 nm to about 8 nm, about 3 nm to about 7 nm, or about 3 nm to about 5 nm, but is not limited thereto.

In an embodiment, the Group IIA metal-containing zinc oxide nanoparticles (e.g., zinc magnesium oxide nanoparticles) may be prepared in an appropriate method without particular limitations. For example, the zinc magnesium oxide nanoparticles may be obtained by adding a zinc compound (e.g., an organic zinc compound such as zinc acetate dihydrate and the like) and a Group IIA metal compound (e.g., an organic Group IIA metal compound such as magnesium acetate tetrahydrate and the like) to a reactor containing an organic solvent (e.g., dimethylsulfoxide) in a desired mole ratio, heating the reactor at a predetermined temperature (e.g., about 40° C. to about 120° C. or about 60° C. to about 100° C.) in the air, and subsequently, adding a precipitation accelerator solution (e.g., an ethanol solution of tetramethylammonium hydroxide pentahydrate) at a predetermined speed in a dropwise fashion to the reactor. The prepared zinc magnesium oxide nanoparticles (e.g., ZnₓMg₁₋ₓO nanoparticle) may be separated from the reaction solution through centrifugation.

According to the inventors of the application, metal oxide nanoparticles, which are wet-synthesized to be used in an electron transport layer, for example, zinc oxide nanoparticles, exhibits an increased leakage current. Without being bound by any particular theory, the wet synthesized zinc oxide-based nanoparticles may have a zinc dangling bond or a hydroxy moiety on the surface, and a carboxylic acid compound (e.g., acetic acid moiety) derived from a precursor during the wet synthesis may coordinate the particle surface, where the dangling bond (Zn:) and hydroxy moiety (Zn—OH) or the acetic acid moiety is thought to increase the leakage current through the electron transport layer. In the device according to an embodiment, a metal or non-metal oxide film (4 or 40) to be described later is formed on an electron transport layer (3 or 30) including the wet synthesized zinc oxide-based nanoparticles to passivate surface defect factors such as the dangling bond, the hydroxy moiety, or the acetic acid moiety formed on the surface of the nanoparticles, having an effect of substantially reducing deep traps in the electron transport layer. As the inventors of the application have confirmed, the electroluminescence device including the continuous metal or non-metal oxide film on the electron transport layer according to an embodiment may reduce the leakage current without the resin aging treatment or the like, while maintaining high luminescent properties such as maximum external quantum efficiency and luminance, and simultaneously, extend a device life-span.

In an embodiment, the continuous metal or non-metal oxide film may be formed to have a thickness of less than about 5 nm on the electron transport layer. The continuous metal or non-metal oxide film may be formed as a thin film, for example, to have a thickness of less than about 5 nm by alternately layering a metal or non-metal precursor and water in a deposition method of precisely controlling a height of one layer to an atomic layer, for example, in an atomic layer deposition (ALD) method. The ALD method, like a conventional chemical vapor deposition (CVD) method, is a method of forming a desired film through chemical changes in precursors of materials to be deposited. However, the ALD method, unlike the conventional CVD method, may deposit a material to a height corresponding to one atomic or molecular layer per cycle regardless of an amount of the material supplied on a substrate. Accordingly, the ALD method allows a thinner film to be uniformly and continuously formed on the electron auxiliary layer than conventional CVD method. In addition, the ALD method may form a uniform film even in a structure with fine steps or gaps. Accordingly, the continuous metal or non-metal oxide film formed on the electron transport layer including the Group IIA metal-containing zinc oxide nanoparticles is thought to effectively passivate traps in the electron transport layer including the Group IIA metal-containing zinc oxide nanoparticles.

The metal or non-metal oxide film may include or be formed of a material with a wider bandgap energy than that of a material forming the electron auxiliary layer. In an embodiment, the electron auxiliary layer may include nanoparticles of Group IIA metal, for example, magnesium-containing zinc oxide, where the metal or non-metal oxide film may include or be formed of a material having a bandgap energy of greater than or equal to about 4.5 electron volts (eV). In an embodiment, for example, the metal or non-metal oxide film may include or be formed of an oxide of aluminum, silicon, tin, magnesium, tungsten, or a combination thereof. In an embodiment, for example, the metal or non-metal oxide film may include Al₂O₃, SiO₂, SnO₂, MgO, WO₃, or a combination thereof but is not limited thereto. In an embodiment, the metal or non-metal oxide film may include Al₂O₃ but is not limited thereto.

The thickness of the oxide film of the metal or non-metal may be less than about 5 nm, for example, greater than 0 nm and less than or equal to about 4.5 nm, greater than or equal to about 1 nm and less than or equal to about 4.5 nm, greater than or equal to about 1 nm and less than or equal to about 4 nm, greater than or equal to about 1 nm and less than or equal to about 3.5 nm, greater than or equal to about 1 nm and less than or equal to about 3 nm, greater than or equal to about 1.5 nm and less than or equal to about 4.5 nm, greater than or equal to about 1.5 nm and less than or equal to about 4 nm, greater than or equal to about 1.5 nm and less than or equal to about 3.5 nm, greater than or equal to about 1.5 nm and less than or equal to about 3 nm, greater than or equal to about 2 nm and less than or equal to about 4.5 nm, greater than or equal to about 2 nm and less than or equal to about 4 nm, or about 3 nm, but is not limited thereto. If the thickness of the oxide film of the metal or non-metal is greater than or equal to about 5 nm, the external quantum efficiency (EQE) of the device may increase, but the driving voltage may increase, and the device characteristics, such as, for example, current density and luminance, may decrease.

In embodiments of the disclosure, as can be seen from Examples described below, by forming a continuous metal or non-metal oxide film in the thickness range above on an electron transport layer including Group IIA metal-containing zinc oxide nanoparticles, driving voltage of the device is lowered, current density is increased, external quantum efficiency (EQE) and luminance are increased, and life-span of the device is significantly increased. Although not wishing to be bound by a particular theory, it is thought that this effect is due to the efficient passivation of traps present in the electron transport layer including the Group IIA metal-containing zinc oxide nanoparticles by the continuous metal or non-metal oxide film. As can be confirmed from Examples described below, in embodiments of an electroluminescence device including a continuous metal or non-metal oxide film, for example, alumina (Al₂O₃), on an electron transport layer, trap emission having a peak wavelength of about 550 nm emitted from zinc magnesium oxide nanoparticles included in the electron transport layer is directly confirmed to be reduced compared to a device not including the metal or non-metal oxide film on the electron transport layer. In such embodiments, a device including a continuous metal or non-metal oxide film on an electron transport layer may increase luminous intensity of the light emitting layer including semiconductor nanocrystals, and at the same time, significantly increase the time over which the luminous intensity of the light emitting layer decreases.

In embodiments, the thickness of the electron transport layer 3 or 30 may be greater than or equal to about 3 nm, greater than or equal to about 5 nm, greater than or equal to about 6 nm, greater than or equal to about 7 nm, greater than or equal to about 8 nm, greater than or equal to about 9 nm, greater than or equal to about 10 nm, greater than or equal to about 11 nm, greater than or equal to about 12 nm, greater than or equal to about 13 nm, greater than or equal to about 14 nm, greater than or equal to about 15 nm, greater than or equal to about 16 nm, greater than or equal to about 17 nm, greater than or equal to about 18 nm, greater than or equal to about 19 nm, greater than or equal to about 20 nm, greater than or equal to about 21 nm, greater than or equal to about 22 nm, greater than or equal to about 23 nm, greater than or equal to about 24 nm, greater than or equal to about 25 nm, greater than or equal to about 26 nm, greater than or equal to about 27 nm, greater than or equal to about 28 nm, greater than or equal to about 29 nm, greater than or equal to about 30 nm, greater than or equal to about 31 nm, greater than or equal to about 32 nm, greater than or equal to about 33 nm, greater than or equal to about 34 nm, or greater than or equal to about 35 nm. In addition, the thickness of the electron transport layer 3 or 30 may be less than or equal to about 90 nm, less than or equal to about 80 nm, less than or equal to about 70 nm, less than or equal to about 60 nm, less than or equal to about 50 nm, less than or equal to about 45 nm, less than or equal to about 40 nm, or less than or equal to about 35 nm.

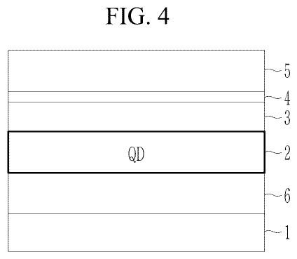

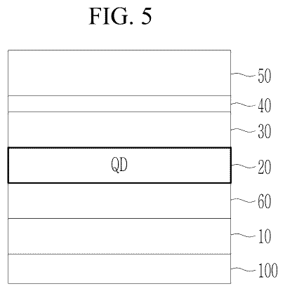

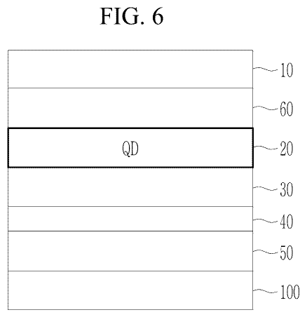

Referring to FIGS. 4 to 6, the electroluminescence device according to an embodiment may further include a hole auxiliary layer. FIG. 4 is a schematic view of an embodiment of an electroluminescence device further including a hole auxiliary layer 6 between the anode 1 and the light emitting layer 2 in the electroluminescence device of FIG. 1, and FIGS. 5 and 6 are schematic views of embodiments of an electroluminescence device further including a hole auxiliary layer 60 between the anode 10 and the light emitting layer 20 in the electroluminescence devices of FIGS. 2 and 3, respectively. The hole auxiliary layer 6 or 60 may include a hole injection layer, a hole transport layer, and/or an electron (or hole) blocking layer. The hole auxiliary layer 6 or 60 may be a single-component layer or may have a multilayer structure in which adjacent layers include different components.

The hole auxiliary layer 6 or 60 may have a HOMO energy level that can be matched with the HOMO energy level of the light emitting layer 2 or 20 to enhance the mobility of holes transferred from the hole auxiliary layer to the light emitting layer 2 or 20. In an embodiment, the hole auxiliary layer 6 or 60 may include a hole injection layer disposed close to the anode 1 or 10 and a hole transport layer disposed close to the light emitting layer 2 or 20.

The material included in the hole auxiliary layer 6 or 60 (e.g., the hole transport layer, the hole injection layer, or the electron blocking layer) is not particularly limited, and may include, for example, poly(9,9-dioctyl-fluorene-co-N-(4)-butylphenyl)-diphenylamine) (TFB), polyarylamine, poly(N-vinylcarbazole) (PVK), poly(3,4-ethylenedioxythiophene) (PEDOT), poly(3,4-ethylenedioxythiophene) polystyrene sulfonate (PEDOT:PSS), polyaniline, polypyrrole, N,N,N′,N′-tetrakis(4-methoxyphenyl)-benzidine (TPD), 4,4′-bis [N-(1-naphthyl)-N-phenyl-amino]biphenyl (alpha-NPD), m-MTDATA (4,4′,4″-Tris [phenyl(m-tolyl)amino]triphenylamine), 4,4′,4″-tris(N-carbazolyl)-triphenylamine (TCTA), 1,1-bis [(di-4-toylamino)phenylcyclohexane (TAPC), a p-type metal oxide (e.g., NiO, WO₃, MoO₃, etc.), a carbon-based material such as graphene oxide, or a combination thereof, but is not limited thereto.

In the auxiliary layer(s), the thickness of each layer may be appropriately selected. In an embodiment, for example, the thickness of each layer may be greater than or equal to about 5 nm, greater than or equal to about 10 nm, greater than or equal to about 15 nm, or greater than or equal to about 20 nm and less than or equal to about 100 nm, less than or equal to about 90 nm, less than or equal to about 80 nm, less than or equal to about 70 nm, less than or equal to about 60 nm, less than or equal to about 50 nm, for example, less than or equal to about 40 nm, less than or equal to about 35 nm, or less than or equal to about 30 nm, but is not limited thereto.

An electroluminescence device according to an embodiment may have a normal structure. In an embodiment, in the device, anode 10 disposed on the transparent substrate 100 may include a metal oxide-based transparent electrode (e.g., an ITO electrode), and cathode 50 facing the anode 10 may include a conductive metal (e.g., having a relatively low work function, Mg, Al, etc.). The hole auxiliary layer 60 (e.g., a hole injection layer such as PEDOT:PSS and/or p-type metal oxide, and/or a hole transport layer such as TFB and/or polyvinylcarbazole (PVK)) may be provided between the transparent electrode 10 and the light emitting layer 20. The hole injection layer may be disposed close to the transparent electrode 10 and the hole transport layer may be disposed close to the light emitting layer 20. An electron transport layer 30 is arranged between the light emitting layer 20 and the cathode 50. Since the light emitting layer 20 and the electron transport layer 30 have a same configuration as the light emitting layer and the electron transport layer described in FIGS. 1 to 4, any repetitive detailed description thereof will be omitted.

In an embodiment, a method for producing an electroluminescence device includes forming a light emitting layer including the semiconductor nanocrystals on a first electrode; forming an electron transport layer including Group IIA metal-containing zinc oxide nanoparticles on the light emitting layer; forming a continuous metal or non-metal oxide film on the electron transport layer; and, forming a second electrode on the continuous oxide film of metal or non-metal.

As described above, in the electroluminescence device according to an embodiment, the formation of the continuous metal or non-metal oxide film on the electron transport layer may include alternately layering a metal or non-metal precursor and water on the electron transport layer in an ALD method. This method, on the electron transport layer of the electroluminescence device according to an embodiment, may uniformly form a thin film with a thickness of less than about 5 nm, for example, about 1 nm to about 4.5 nm, for example, about 1.5 nm to about 4.5 nm, for example, about 1.5 nm to about 4 nm.

The method for producing an electroluminescence device may further include optionally forming a hole auxiliary layer (e.g., by deposition or coating) on a substrate on which an electrode, e.g., a first electrode, or an anode is formed. The method of forming the electrode and the hole auxiliary layer can be appropriately selected and is not particularly limited. The method of forming the light emitting layer is as described above.

The formation of the electron transport layer includes preparing a dispersion in which the Group IIA metal-containing zinc oxide nanoparticles are dispersed and applying the dispersion on the light emitting layer to form the film. The application may include spin coating and the like but is not limited thereto. The formation of the electron transport layer may further optionally include a heat treatment after applying the dispersion in which the Group IIA metal-containing zinc oxide nanoparticles are dispersed onto the light emitting layer.

The method may further include washing the film by using a washing organic solvent. The washing may include adding the solvent in a dropwise fashion and/or spin coating it but is not limited thereto.

In the forming of the electron transport layer, the organic solvent for forming the dispersion may be a C1 to C10 alcohol solvent, or a combination thereof.

The dispersion may be applied onto the light emitting layer by an appropriate method (e.g., spin coating or drop casting). The applied film may be heat treated at a predetermined temperature, for example, less than about 160° C., for example, less than or equal to about 150° C., or less than or equal to about 120° C., for removal of an organic solvent, etc. The heat treatment may be performed under an inert gas atmosphere, such as nitrogen or argon, or under air. The heat treatment temperature may be less than about 120° C., less than or equal to about 115° C., less than or equal to about 110° C., less than or equal to about 105° C., less than or equal to about 100° C., less than or equal to about 95° C., less than or equal to about 90° C., or less than or equal to about 85° C. The heat treatment temperature may be greater than or equal to about 40° C., greater than or equal to about 50° C., greater than or equal to about 60° C., greater than or equal to about 65° C., greater than or equal to about 70° C., or greater than or equal to about 75° C.

in an embodiment of the disclosure, the continuous metal or non-metal oxide film may be formed on the electron transport layer in an ALD method. As described above, the ALD method is a laminating method of forming a film with a height of one atomic or molecular layer per cycle, and in the electroluminescence device according to an embodiment, the thin metal or non-metal oxide film with a desired thickness may be uniformly, continuously, and efficiently formed on the electron transport layer. The metal or non-metal oxide film is formed by alternately layering a metal or non-metal precursor and water in the ALD method through a chemical reaction between the metal or non-metal precursor and the water. The metal or non-metal precursor may be a precursor of aluminum, silicon, tin, tungsten, magnesium, or a combination thereof. For example, salts or complexes with an organic compound of the metal or the non-metal may be further included, but the invention is not limited thereto.

The method for fabricating an electroluminescence device, after forming the metal or non-metal oxide film, may include forming a second electrode, for example, a cathode. A method of forming the second electrode may be the same as or similar to the method of forming the first electrode but include any method, for example, deposition or coating, and the like. The material and producing method for forming the second electrode are the same as described above.

The method for fabricating an electroluminescence device, after forming the second electrode (e.g., after applying a polymerizable resin on the second electrode), may further include aging the resin by allowing the electroluminescence device to stand at less than or equal to about 100° C., about 40° C. to about 90° C., about 50° C. to about 80° C., or about 60° C. to about 70° C. The resin aging time may be appropriately adjusted, for example, greater than or equal to about 10 hours, greater than or equal to about 20 hours, greater than or equal to about 24 hours, greater than or equal to about 48 hours, greater than or equal to about 72 hours, greater than or equal to about 96 hours, or greater than or equal to about 100 hours. The resin aging time may be less than about 7 days, less than or equal to about 6 days, less than or equal to about 5 days, less than or equal to about 4 days, less than or equal to about 3 days, or less than or equal to about 2 days. The electroluminescence device according to an embodiment may achieve improved electroluminescence properties under the relatively short resin aging time. In an embodiment, the electroluminescence device according to an embodiment may achieve excellent electroluminescence property improvement without the aging treatment.

The polymerizable resin may be a resin used for encapsulation of an electroluminescent device, and its type is not particularly limited. The polymerizable resin may be an acrylic resin such as poly(meth)acrylate, poly(methacrylic acid), and the like, a urethane resin, a vinyl resin, an epoxy resin, or a combination thereof. The polymerizable resin may have a polymerizable moiety (e.g., a carbon-carbon double bond, etc.).

The electroluminescence device of an embodiment may exhibit improved electroluminescence properties. In the electroluminescence device of an embodiment, the resin aging may be performed within relatively shortened time.

The electroluminescence device of an embodiment may have a maximum external quantum efficiency (EQE) of greater than or equal to about 7%, greater than or equal to about 7.5%, greater than or equal to about 7.7%, greater than or equal to about 8%, greater than or equal to about 8.5%, greater than or equal to about 9%, greater than or equal to about 9.5%, greater than or equal to about 10%, greater than or equal to about 10.5%, greater than or equal to about 11%, greater than or equal to about 11.5%, greater than or equal to about 12%, greater than or equal to about 12.5%, greater than or equal to about 13%, greater than or equal to about 13.5%, or greater than or equal to about 14%. The electroluminescence device of an embodiment may have a maximum external quantum efficiency (EQE) of less than or equal to about 100%, less than or equal to about 90%, less than or equal to about 80%, less than or equal to about 70%, less than or equal to about 60%, less than or equal to about 50%, less than or equal to about 40%, less than or equal to about 30%, or less than or equal to about 20%.

The electroluminescence device may have a maximum luminance of greater than or equal to about 1500 candelas per square meter (cd/m²), for example, greater than or equal to about 1600 cd/m², greater than or equal to about 1700 cd/m², greater than or equal to about 1800 cd/m², greater than or equal to about 1900 cd/m², greater than or equal to about 2000 cd/m², greater than or equal to about 2100 cd/m², greater than or equal to about 2200 cd/m², greater than or equal to about 2300 cd/m², greater than or equal to about 2400 cd/m², greater than or equal to about 2600 cd/m², or greater than or equal to about 2700 cd/m². The electroluminescence device may have a maximum luminance of less than or equal to about 5000 cd/m², less than or equal to about 4000 cd/m², less than or equal to about 3000 cd/m², or less than or equal to about 2900 cd/m².

The electroluminescence device according to an embodiment, when driven at a predetermined luminance (e.g., 1000 cd/m²), may exhibit T70 of greater than or equal to about 10 hours, for example, greater than or equal to about 15 hours, greater than or equal to about 17 hours, greater than or equal to about 18 hours, greater than or equal to about 20 hours, greater than or equal to about 23 hours, greater than or equal to about 25 hours, or greater than or equal to about 27 hours. The T70 may be, for example, within a range of about 10 hours to about 30 hours, about 12 hours to about 30 hours, about 15 hours to about 30 hours, about 15 hours to about 28 hours, about 17 hours to about 28 hours, about 20 hours to about 28 hours, or a combination thereof.

Another embodiment relates to a display device including the aforementioned electroluminescence device.

The display device may include a first pixel and a second pixel configured to emit light of a color differing from that of the first pixel. In the first pixel, the second pixel, or a combination thereof, the electroluminescence device according to an embodiment may be disposed. In an embodiment, the display device may further include a blue pixel, a red pixel, a green pixel, or a combination thereof. In the display device, the red pixel may include a red light emitting layer including a plurality of red light emitting semiconductor nanoparticles, the green pixel may include a green light emitting layer including a plurality of green light emitting semiconductor nanoparticles, and the blue pixel may include a blue light emitting layer including a plurality of blue light emitting semiconductor nanoparticles.

The display device may include or be a portable terminal device, a monitor, a notebook computer, a television, an electric sign board, a camera, or an electronic component.

Specific examples will hereinafter be described in detail. However, the examples described below are only examples for specifically illustrating or explaining the disclosure, and the scope of the disclosure is not limited thereto.

### EXAMPLES

### Analysis Method

### [1] Electroluminescence Spectroscopic Analysis

A current according to a voltage is measured with a Keithley 2635B source meter, while the voltage is applied, and a CS2000 spectrometer is used to measure EL light emitting luminance.

### [2] Life-Span Characteristics

T70(h): When driven at a given luminance (e.g., 1000 cd/m²), the time (hr) it takes for the luminance to reach 70% of the initial luminance of 100% is measured.

Here, the relative life-span is determined based on the measured T70(h) value.

### [3] TEM Analysis

A transmission electron microscope analysis of the prepared nanoparticles is performed by using an UT F30 Tecnai electron microscope.

### [4] Photoluminescence Analysis

Photoluminescence (PL) analysis is performed by using a Hitachi F-7000 spectrophotometer.

The following synthesis is performed under an inert gas atmosphere (under a nitrogen flowing condition), unless otherwise specified. A precursor content is a mole content, unless otherwise specified.

### Synthesis Example 1: Preparation of Blue Light-Emitting ZnSeTe/ZnSeS Semiconductor Nanoparticles

A Se/TOP stock solution and a Te/TOP stock solution are prepared by dispersing selenium (Se) and tellurium (Te) in trioctylphosphine (TOP). To a reactor containing trioctylamine, 0.125 millimole (mmol) of zinc acetate with oleic acid is added, and then, heated at 120° C. under vacuum. After 1 hour, an atmosphere in the reactor is converted into nitrogen.

After heating the reactor at 300° C., the Se/TOP stock solution and the Te/TOP stock solution in a Te/Se ratio of 1/20 are rapidly injected thereinto. When a reaction is completed, after rapidly cooling down the reaction solution to room temperature, acetone is added thereto, centrifuged to obtain precipitates, and then the precipitates are dispersed in toluene to obtain a ZnSeTe core.

1.8 mmol of zinc acetate with oleic acid is put in a flask containing trioctylamine, and then, vacuum-treated at 120° C. for 10 minutes. The flask is internally substituted with nitrogen (N₂), and then, heated up to 180° C. Subsequently, the obtained ZnTeSe core is added thereto, and Se/TOP stock solution and S/TOP stock solution are injected thereinto. A reaction temperature thereof is set at about 280° C. When a reaction is completed, the reactor is cooled down, and the prepared nanocrystals are centrifuged with ethanol, and then, dispersed in toluene to obtain blue light emitting semiconductor nanoparticles.

Through a photoluminescence analysis, the semiconductor nanoparticles turn out to have a maximum emission wavelength of 455 nm.

The synthesized semiconductor nanoparticles (optical density of 0.25 at 420 nm, 6 milliliters (mL)) are precipitated with ethanol, and centrifuged, and then, the precipitates are dispersed again in cyclohexane to obtain a cyclohexane dispersion. 0.022 mmol of zinc chloride dissolved in ethanol is added to the cyclohexane dispersion, and then, stirred at 80° C. for 30 minutes. The treated semiconductor nanoparticles are recovered by centrifugation, and then, dispersed in octane to obtain an octane dispersion.

### Synthesis Example 2: Synthesis of Red Light Emitting InP/ZnSe/ZnS Quantum Dot

### (1) Preparation of InP Core

In a 300 mL reaction flask, 0.2 mmol of indium acetate and 0.6 mmol of palmitic acid are dissolved in 1-octadecene and heated to 120° C. under vacuum. After 1 hour, the atmosphere in the reactor is converted into nitrogen. After heating the reactor at 280° C., a mixed solution of 0.1 mmol of tris(trimethylsilyl)phosphine (TMS3P) and 1 ml of trioctylphosphine is rapidly injected thereinto, and reacted for 30 minutes. Acetone is added to the reaction solution cooled down to room temperature, and then, the precipitates centrifuged therefrom are dispersed again in toluene. Ultraviolet (UV) spectroscopy of the obtained InP semiconductor nanocrystals is performed, and the diameter of the InP core obtained is confirmed as approximately 3 nm.

### (2) Preparation of InP/ZnSe/ZnS Quantum Dots

Se powder and S powder are dissolved in TOP to prepare a 2 molar (M) of Se/TOP stock solution and a 1 M of S/TOP stock solution, respectively.

In a 200 mL reaction flask, zinc acetate and oleic acid are dissolved in trioctylamine, and vacuum-treated at 120° C. for 10 minutes. After substituting inside of the reaction flask with nitrogen (N₂), while increasing the temperature of the solution to 320° C., a toluene dispersion of the InP core synthesized as described above is injected thereinto, and sequentially, the prepared Se/TOP stock solution is injected thereinto over several times. A reaction is performed to obtain a reaction solution including a particle having a ZnSe shell disposed on the core. A total reaction time is about 100 minutes, and a total amount of Se used per 1 mol of indium is about 8 mols.

Subsequently, at the reaction temperature, the S/TOP stock solution is injected into the reaction solution. A reaction is performed to obtain a reaction solution including a particle having a ZnS shell disposed on the ZnSe shell. A total reaction time is 60 minutes, and a total amount of S used per 1 mol of indium is about 8 mols. Subsequently, the solution is cooled to room temperature, an excessive amount of ethanol is added thereto, centrifuged, and after discarding a supernatant, precipitates therefrom are dried and dispersed in toluene to obtain an InP/ZnSe/ZnS quantum dot solution.

When the obtained quantum dot is subjected to luminescence analysis, a luminescence peak appears at 628 nm, a full width at half maximum (FWHM) is 36 nm, and quantum efficiency is 78%.

In addition, when the quantum dot is subjected to UV spectroscopy analysis, the ZnSe shell right on the core of the quantum dot has a thickness of about 1.7 nm (about 6 monolayers), an outmost layer, the ZnS shell formed on the ZnSe shell, has a thickness of 0.3 nm, and the obtained quantum dot has a diameter of about 7.7 nm. In addition, as a result of performing an ICP-AES analysis, a ratio of mols of phosphorus to total mols of indium in the quantum dot is about 0.89, a ratio of moles of zinc to the total moles of indium is 17.6, and a ratio of moles of selenium to the total moles of indium is 8.

### Synthesis Example 3: Synthesis of ZnMgO Nanoparticles

Zinc acetate dihydrate and magnesium acetate tetrahydrate are added to a reactor containing dimethylsulfoxide at a mole ratio according to the following chemical formula, and heated at 60° C. in the air. Subsequently, an ethanol solution of tetramethylammonium hydroxide pentahydrate is added to the reactor. After stirring the obtained mixture for 1 hour, precipitates formed therein are centrifuged, and then, the precipitates are dispersed again in ethanol to obtain Zn₁₋ₓMgₓO nanoparticles (x=0.15). The bandgap energy of the obtained Zn₁₋ₓMgₓO nanoparticles (x=0.15) is about 3.7 electron Volt (eV).

The obtained nanoparticles are subjected to a transmission electron microscope analysis. As a result, the particles have an average size of about 3 nm.

### Examples 1 to 3: Production of Electroluminescence Devices

According to the method below, an electroluminescence device with a structure of ITO/NiOx/SAM/pTPD/QD light emitting layer/ZnMgO/Al₂O₃/Al is produced.

First, a glass substrate on which ITO is deposited is surface-treated with UV-ozone for 15 minutes, and a NiOx film as a hole injection layer (HIL) is formed thereon by coating a butanol solution in which NiOx nanoparticles of p-type metal oxide are dispersed. On the NiOx film, a self-assembled monolayer (SAM, 4-trifluoromethyl benzoic acid) that helps hole transport characteristics is formed, and subsequently, an about 30 nm-thick hole auxiliary layer as an electron blocking layer is formed by coating and curing N,N,N′,N′-tetrakis(4-methoxyphenyl)-benzidine (TPD).

On the hole auxiliary layer, a toluene dispersion of the quantum dots (InP/ZnSe/ZnS) according to Synthesis Example 2 is spin-coated to form a 32 nm-thick light emitting layer.

On the light emitting layer, a dispersion of the ZnMgO nanoparticles according to Synthesis Example 3 is spin-coated and heat-treated at 80° C. to form an electron transport layer (a thickness: 20 nm).

After forming the electron transport layer, an aluminum precursor, i.e., trimethyl aluminum (TMA), and water (H₂O) are alternately laminated to form a continuous Al₂O₃ film with each thickness of 1 nm (Example 1), 3 nm (Example 2), and 5 nm (Example 3), respectively, on the electron transport layer in an ALD method. In the ALD method, the TMA gas is firstly purged, and then, H₂O vapor is purged for forming an oxide of the aluminum, which consists of one cycle. By performing 5 cycles, 10 cycles, and the like, aluminum and oxygen can alternately be laminated to form the Al₂O₃ film. The temperature was maintained at 100° C. Generally, the Al₂O₃ film grows at about 1.1 angstrom per cycle (Å/cycle). The obtained Al₂O₃ film has a bandgap energy of about 7 to 8 eV.

On the obtained Al₂O₃ film, aluminum (Al) is vacuum-deposited to be 100 nm thick to form a cathode, thereby manufacturing a luminescence device.

The manufactured luminescence device is measured with respect to electroluminescence properties, and the results are shown in Table 1.

### Comparative Example 1: Production of Electroluminescence Devices

A device is manufactured in the same manner as in Examples 1 to 3 except that a dispersion of the zinc magnesium oxide nanoparticles according to Synthesis Example 2 is used to form an electron transport layer on the light emitting layer, and the continuous Al₂O₃ layer is not formed, but aluminum (Al) is directly vacuum-deposited to form a 100 nm-thick cathode.

### Evaluation 1: Evaluation of Electroluminescence Properties

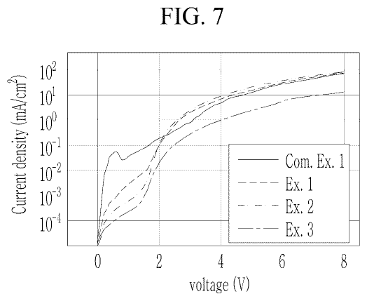

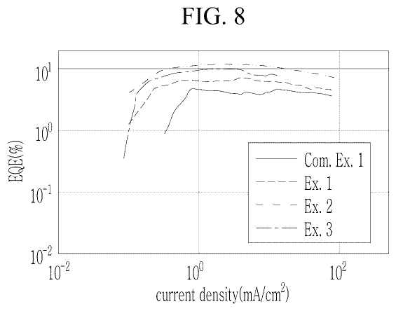

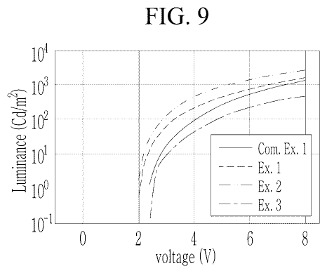

Each of the devices according to the examples and the comparative example was measured with respect to electroluminescence properties, and the results are shown in Table 1 and FIGS. 7 to 10.

TABLE 1

| | | | | | Maximum |
|---|---|---|---|---|---|
| | EQE | maxEQE | Driving | Current density | luminance |
| Device | (%) | @ Vol (V) | voltage (V) | (@8 V) (mA/cm²) | (cd/m²) |
| Comparative | 4.78 | 3 | 2.4 | 80 | 1353 |
| Example 1 | | | | | |
| Example 1 | 7.34 | 3.6 | 2 | 79 | 1664 |
| Example 2 | 11.89 | 3 | 2 | 84 | 2708 |
| Example 3 | 9.91 | 4.8 | 2.4 | 13 | 471 |

maxEQE @ Vol: the voltage at which the EQE has the maximum value.

Referring to the results of Table 1, the electroluminescence devices according to Examples 1 and 2, compared to the device according to Comparative Example 1, exhibit improved EQE and luminance. In particular, the electroluminescence device of Example 2 in which a 3 nm-thick continuous Al₂O₃ film is formed on an electron transport layer, exhibits significantly increased EQE and luminance, compared to the electroluminescence device of Comparative Example 1. In addition, the devices of Examples 1 and 2, compared to the device of Comparative Example 1, also exhibit a significantly reduced driving voltage. On the contrary, the device of Example 3, in which a Al₂O₃ film is formed to be 5 nm thick on an electron transport layer, exhibits increased EQE, compared to the devices of Comparative Example 1 and Example 1, but the same driving voltage as the device of Comparative Example 1, in which the Al₂O₃ film is not formed, and in addition, the device of Example 3 is confirmed to exhibit sharply reduced current and luminance due to an increase in resistance, thereby resulting in much deteriorated characteristics of the device.

Graphs of current density to a voltage, external quantum efficiency (EQE) to the current density, luminance to the voltage, and light emitting life-span related luminous intensity to time of each of the devices are respectively shown in FIGS. 7 to 10. Table 1 shows data organized from the results shown in FIGS. 7 to 10.

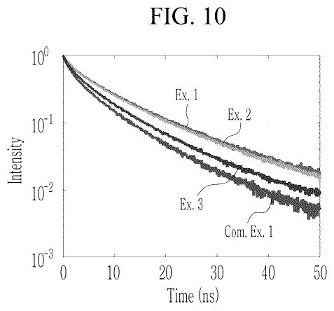

FIG. 10 is a graph showing a decrease in luminous intensity of a device over time in the time-resolved photoluminescence concept. The measurement is performed by exciting a light emitting layer with short wavelength laser light to measure PL luminous intensity according to time that it arrives. A degree of the decrease in the luminous intensity over time may be used to check an environment of excitons generated within a light emitting body and their surrounding quenchers. Referring to FIG. 10, the devices of Examples 1 and 2 having each 1 nm-thick and 3 nm-thick continuous Al₂O₃ film exhibit better delayed luminescence than that of Comparative Example 1, and thus, are confirmed to have longer time that maintains PL intensity than the device of Comparative Example 1.

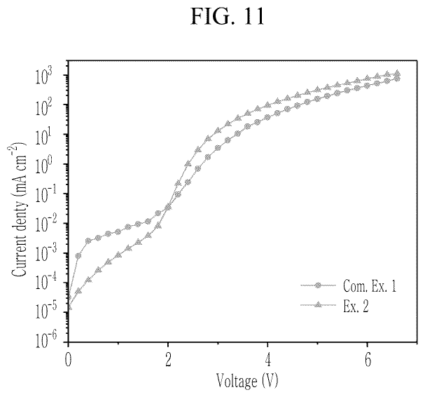

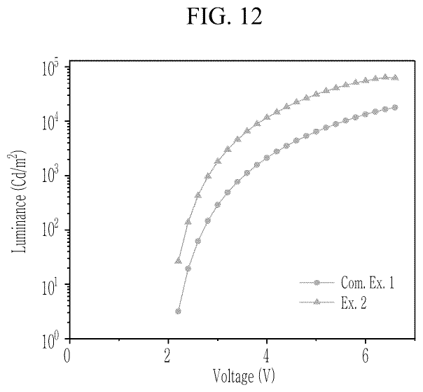

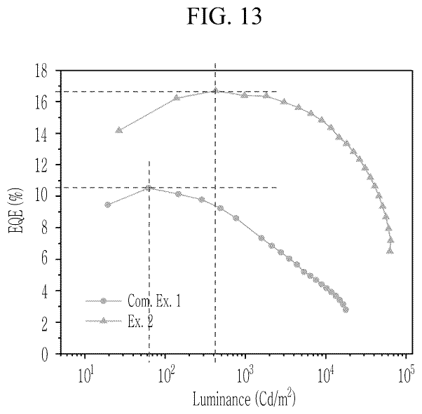

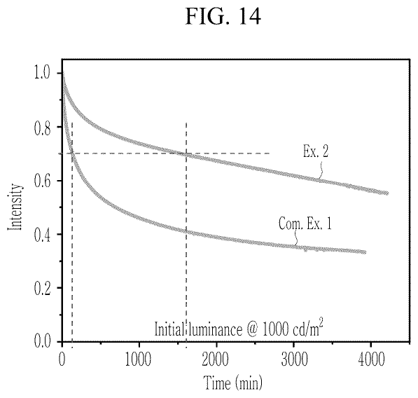

On the other hand, compared to the device of Comparative Example 1, in which an Al₂O₃ film is not formed on an electron transport layer including zinc magnesium oxide nanoparticles, the device of Example 2, in which a 3 nm-thick Al₂O₃ film is formed on an electron transport layer, exhibits the most desired characteristics, and FIGS. 11 to 14 are graphs comparing current density to voltage, luminance to voltage, EQE, that is, maximum EQE to the luminance, and luminous intensity to time, showing life-span, of the devices. Referring to FIG. 11, the device of Example 2, compared to the device of Comparative Example 1, exhibits a small current amount at a driving voltage of 2 V or less but a much increased current amount after the driving voltage, and referring to FIG. 12, as the voltage increases after the driving voltage, the device of Example 2 exhibits that luminance increases at high levels according to the voltage within all the voltage ranges, compared to the device of Comparative Example 1. In addition, referring to FIG. 13, the device of Comparative Example 1 exhibits maximum EQE of about 10.5%, while the device of Example 2 exhibits significantly increased maximum EQE to about 16.5%, and referring to FIG. 14, compared to the device of Comparative Example 1, the device of Example 2 exhibits a much smaller luminous intensity decrease rate. In particular, as for T70 that light emitting intensity decreases to 70% of the initial luminous intensity, the device of Comparative Example 1 exhibits about 190 minutes, that is, slightly more than 3 hours, but the device of Example 2 exhibits T70 of about 1650 minutes, that is, about 27.5 hours, which is an increase of more than 8 times to that of the device of

### Comparative Example 1

### Evaluation 2: Evaluation of Thin Film Characteristics

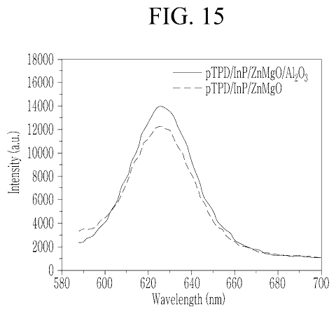

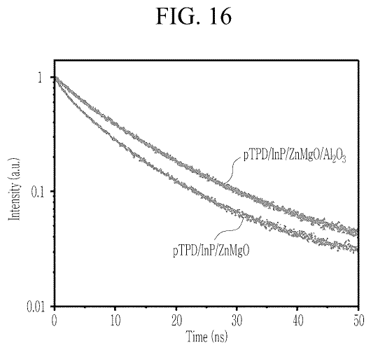

An anode, a cathode, a hole injection layer (HIL), and a hole transport layer (HTL) are omitted, but an electron blocking layer (pTPD), a light emitting layer (InP/ZnSe/ZnS), and an electron transport layer (ZnMgO) are sequentially included, and additionally, an Al₂O₃ layer is formed to be 3 nm thick or not formed on the electron transport layer in an ALD method. Each emitting layer (InP/ZnSe/ZnS) of the thin films is measured with respect to the luminescence characteristics (QD photoluminescence: QD PL) and trap emission reduction time, and the results are respectively shown in graphs of FIGS. 15 and 16.

Referring to FIG. 15, the thin film, in which the Al₂O₃ continuous film is formed on the electron transport layer, exhibits increased QD PL intensity, and referring to FIG. 16, the thin film, in which the Al₂O₃ continuous film is formed on the electron transport layer, exhibits an increase in the reduction time of the QD PL intensity.

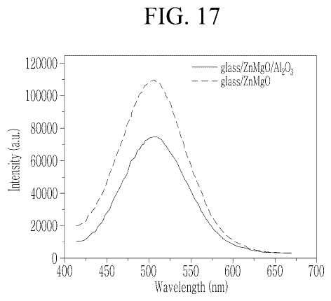

In addition, a case where a dispersion of the zinc magnesium oxide nanoparticles of Synthesis Example 2 alone is coated on a glass substrate and the other case that an Al₂O₃ continuous film is formed on the coating in an ALD method are checked with respect to the luminescence characteristics, and the results are shown in FIG. 17. Referring to FIG. 17, the two thin films are confirmed to exhibit light emission (i.e., trap emission) at about 550 nm or less derived from the zinc magnesium oxide nanoparticles. Herein, the former thin film that the Al₂O₃ continuous film is formed on the zinc magnesium oxide surface, compared to the latter film that the Al₂O₃ continuous film is not formed, is confirmed that the trap emission intensity is significantly reduced.

Based on the results, it would be understood that when a continuous metal or non-metal oxide film may be formed on the zinc magnesium oxide surface in the ALD method, the oxide film may passivate a trap of an electron transport layer that includes Group IIA metal-containing zinc oxide nanoparticles and positioned under the film, reduce the trap emission from the electron transport layer, increase luminescence characteristics of the light emitting layer of an electroluminescence device including the light emitting layer and the electron transport layer, and delay the decrease in luminescence of the quantum dots due to the trap.

As described above, in a electroluminescence device including the quantum dots according to an embodiment, the continuous metal or non-metal oxide film may be formed to be thin and uniform on the electron transport layer including Group IIA metal-containing zinc oxide nanoparticles to effectively passivate the trap of the electron transport layer disposed under the film, thereby significantly increasing electroluminescence properties and life-span of the device, and in addition, the device may not need aging before driving after manufacturing or may be aged with significantly less aging time. Accordingly, such an electroluminescence device may not only dramatically shorten device manufacturing time but also exhibit improved reliability and performance.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. An electroluminescence device, comprising
an anode and a cathode opposite to each other,
a light emitting layer between the anode and cathode,
an electron transport layer between the light emitting layer and the cathode, and
a continuous metal or non-metal oxide film between the electron transport layer and the cathode,
wherein the light emitting layer comprises a plurality of semiconductor nanoparticles, and
the electron transport layer comprises Group IIA metal-containing zinc oxide nanoparticles.

2. The electroluminescence device of claim 1, wherein the continuous metal or non-metal oxide film comprises a material having a bandgap energy greater than a bandgap energy of the Group II metal-containing zinc oxide.

3. The electroluminescence device of claim 1, wherein the continuous metal or non-metal oxide film comprises a material having a bandgap energy of greater than or equal to about 4.5 eV.

4. The electroluminescence device of claim 1, wherein the continuous metal or non-metal oxide film comprises an oxide of at least one selected from aluminum, silicon, tin, magnesium, tungsten, or a combination thereof.

5. The electroluminescence device of claim 1, wherein the continuous metal or non-metal oxide film has a thickness of less than about 5 nm.

6. The electroluminescence device of claim 1, wherein Group IIA metal comprises at least one selected from magnesium, calcium, beryllium, strontium, barium, or a combination thereof.

7. The electroluminescence device of claim 1, wherein the Group IIA metal-containing zinc oxide nanoparticles are represented by Zn₁₋ₓM¹ₓO, wherein M¹ comprises a Group IIA metal, and optionally further includes at least one selected from zirconium (Zr), tungsten (W), lithium (Li), titanium (Ti), yttrium (Y), aluminum (Al), gallium (Ga), indium (In), sodium (Na), potassium (K), cesium (Cs), tin (Sn), cobalt (Co), or vanadium (V), and x is greater than 0 and less than or equal to 0.3.

8. The electroluminescence device of claim 1, wherein
the Group IIA metal-containing zinc oxide nanoparticles are zinc magnesium oxide nanoparticles, and
a molar ratio of zinc to magnesium in the zinc magnesium oxide nanoparticles is about 80:20 to about 95:5.

9. The electroluminescence device of claim 1, wherein the Group IIA metal-containing zinc oxide nanoparticles have an average size of less than or equal to about 10 nm.

10. The electroluminescence device of claim 1, wherein the electron transport layer has a thickness of greater than or equal to about 5 nm and less than or equal to about 60 nm.

11. The electroluminescence device of claim 1, wherein the plurality of semiconductor nanoparticles has an average size of greater than or equal to about 7 nm and less than or equal to about 30 nm.

12. The electroluminescence device of claim 1, wherein each of the plurality of semiconductor nanoparticles comprises a core comprising a first semiconductor nanocrystal, and a shell disposed on the core and comprising a second semiconductor nanocrystal different from the first semiconductor nanocrystal.

13. The electroluminescence device of claim 1, further comprising:
a hole auxiliary layer between the light emitting layer and the anode.

14. The electroluminescence device of claim 1, wherein the electroluminescence device has a maximum external quantum efficiency of greater than or equal to about 7%.

15. The electroluminescence device of claim 1, wherein the electroluminescence device has a maximum luminance of greater than or equal to about 1500 cd/m².

16. A method for producing an electroluminescence device, the method comprising
forming a light emitting layer comprising semiconductor nanocrystals on an anode,
forming an electron transport layer comprising Group IIA metal-containing zinc oxide nanoparticles on the light emitting layer,
forming a continuous metal or non-metal oxide film on the electron transport layer, and
forming a second electrode on the continuous metal or non-metal oxide film.

17. The method of claim 16, wherein the forming the continuous metal or non-metal oxide film comprises alternately depositing metal or non-metal precursors and water on the electron transport layer using an atomic layer deposition method.

18. The method of claim 16, wherein the forming the electron transport layer comprises:
preparing a dispersion in which Group IIA metal-containing zinc oxide nanoparticles are dispersed in an organic solvent; and
applying the dispersion onto the light emitting layer.

19. The method of claim 16, further comprising:
forming a hole auxiliary layer on the anode before forming the light emitting layer.

20. A display device comprising the electroluminescence device of claim 1.
